(19) United States
(12) Patent Application Publication
(10) Pub. No.: US 2017/0164491 A1
(43) Pub. Date: Jun. 8, 2017

(54) Surface Mounted Fastener

(71) Applicants: Robert Bosch, LLC, Broadview, IL (US); Robert Bosch GmbH, Stuttgart (DE)

(72) Inventors: John Janson, Plymouth, MI (US); Ligor Manushi, Northville, MI (US)

(21) Appl. No.: 14/956,563

(22) Filed: Dec. 2, 2015

(51) Int. Cl. H05K 5/00

(52) U.S. Cl. CPC H05K 5/0069

(57) ABSTRACT

A printed circuit board assembly includes a housing and a printed circuit board disposed in the housing. The printed circuit board includes a first surface, an opposed second surface, and an opening-free region. In addition, the printed circuit board includes a fastener disposed within the opening free region and mounted to a surface of the printed circuit board so as to protrude from the surface. The fastener has a size and shape such that the fastener is press fit into a corresponding opening of the housing in such a way as to secure the printed circuit board relative to the housing.

### BACKGROUND

### 1. Field of the Invention

The present invention relates to printed circuit board assembly including a printed circuit board (PCB) disposed in a housing, in which the PCB includes a surface mounted fastener that permits the PCB to be attached to the housing via press fit of the fastener in an opening in the housing.

### 2. Description of the Related Art

Many vehicles include sensor assemblies as a part of safety and/or convenience packages, where one or more sensors are used to monitor vehicle surroundings as well as the vehicle interior. An example of such an assembly is an on-board camera system. Such camera systems are relatively small so as to be unobtrusive. To that end, the components of the camera including the optics and controlling electronics are also made small. As a result of the limited size of the printed circuit board that supports the controlling electronics, improved efficiency in use of the printed circuit board area is desired in order to maximize sensor function and operability.

### SUMMARY

In some aspects, a printed circuit board device includes a printed circuit board that includes electrically conductive layers laminated onto a non-conductive substrate, the printed circuit board having a first surface, an opposed second surface, and an opening-free region. In addition, a fastener is disposed within the opening free region and protrudes from one of the first surface and the second surface. The fastener is configured to be press fit into an opening of a housing in such a way as to secure the printed circuit board relative to the housing.

The printed circuit board device may include one or more of the following features: The fastener is fixed to the one of the first surface and the second surface. The fastener is soldered to the one of the first surface and the second surface. The fastener is an elongated rod. The fastener includes surface features that enhance engagement with a surface of the opening. The surface features comprise a helical thread. The surface features comprise a knurl. The fastener includes a base having a first cross-sectional diameter and a shank that protrudes from the base and has a second cross sectional diameter, where the second cross sectional diameter is less than the first cross sectional diameter. The printed circuit board is free of guide posts and free of location features for locating guide posts of a housing.

In some aspects, a printed circuit board assembly includes a housing and a printed circuit board device disposed in the housing. The housing defines an opening. The printed circuit board device includes a printed circuit board that includes electrically conductive layers laminated onto a non-conductive substrate. The printed circuit board has a first surface, an opposed second surface, an opening-free region; and a fastener. The fastener is disposed within the opening free region and protrudes from one of the first surface and the second surface. The fastener includes a size and shape such that the fastener is press fit into the opening in such a way as to secure the printed circuit board relative to the housing.

The printed circuit board assembly includes one or more of the following features: The fastener is an elongated rod. The fastener includes surface features that enhance engagement with a surface of the opening. The fastener includes a base having a first cross-sectional diameter and a shank that protrudes from the base and has a second cross sectional diameter, wherein the second cross sectional diameter is less than the first cross sectional diameter, and a shoulder is disposed at the intersection of the base and the shank. The assembly further includes a second printed circuit board having a through hole. The second printed circuit board is disposed between the first printed circuit board and the housing, and the fastener passes through the through hole and the shoulder abuts a surface of the second printed circuit board. The fastener includes a base and a shank that protrudes from the base. One end of the base adjoins the one of the first surface and the second surface and an opposed end of the base adjoins the shank. The base is disposed between the shank and the one of the first surface and the second surface, and the shank extends away from the printed circuit board in a direction perpendicular to the one of the first surface and the second surface. The printed circuit board is free of guide posts and free of location features for locating guide posts of a housing, and the housing is free of guide posts and free of location features for locating guide posts of a printed circuit board.

In some aspects, a method of assembling a printed circuit board assembly includes fixing a fastener to a first surface of a printed circuit board in region of the printed circuit board that is free of openings; and inserting the fastener into an opening of a housing to form a press fit connection between the fastener and the housing.

The method may include one or more of the following method steps or features: The step of fixing a fastener to a surface of a printed circuit board comprises soldering the fastener to the surface of the printed circuit board. The method further includes applying a force to a second surface of the printed circuit board at a location that is aligned with the fastener, wherein the second surface is opposed to the first surface and the force urges the fastener into the press fit connection with the opening of the housing. The inserting step includes, prior to inserting the fastener into the opening of the housing, inserting the fastener into a through hole of a second printed circuit board such that the fastener extends through the through hole.

In some aspects, a housing, for example a camera housing, includes a PCB having a surface mounted fastener. The fastener is secured to an outside surface of the PCT and protrudes in a direction normal to and away from the outside surface. This is advantageous relative to some prior art PCB assemblies 100 (FIGS. 8 and 9) in which the PCB 132 is secured to a housing using conventional screws 140. In the prior PCB assemblies 100, the PCB 132 includes through holes 138 that receive the screws 140. However, the process for assembling a PCB 132 to a housing 120 using the screws 140 requires an expensive automated assembly station with precision controls. Moreover, such prior art PCB assemblies 100 require that the through holes 138 be formed in the PCB 132 to receive the screw, and further require the formation of location features 139a, 139b on the PCB 132 and the housing 120 that are used to pre-align the PCB 132 prior to the screws 140 being installed. By providing the PCB with the surface mount fastener, the areas of the PCB that would have been used for the through holes 138 and location features 139a can instead be used to support additional elements of the electronics system such as electrical traces and/or electronic components. As a result, improved efficiency in use of the PCB area is achieved.

Advantageously, the PCB including the surface mount fastener can be assembled using existing electronics population equipment and the surface mount fastener can be joined to the PCB by known joining methods such as soldering. In addition, the PCB having the surface mount fastener can be mounted in the housing by press fitting the surface mount fastener within openings within the housing, whereby no expensive and/or precision assembly equipment is required, and manufacturing costs associated with fixing the PCB within a housing can be reduced.

### BRIEF DESCRIPTION OF THE DRAWINGS

FIG. 1 is a side cross-sectional view of a vehicle camera illustrating use of a PCB within the camera housing.

FIG. 2 is an exploded view of a PCB assembly including a PCB having a surface mount fastener and a housing portion.

FIG. 3 is a perspective cross-sectional view of a portion of the assembled PCB assembly of FIG. 2.

FIG. 4 is a side view of an alternative embodiment fastener.

FIG. 5 is a side view of another alternative embodiment fastener.

FIG. 6 is a cross-sectional view of a portion of an alternative embodiment PCB assembly.

FIG. 7 is a flow chart illustrating a method of assembling a PCB assembly.

FIG. 8 is a perspective cross-sectional view of a portion of a prior art PCB assembly.

FIG. 9 is an exploded view of the prior art PCB assembly of FIG. 8.

### DETAILED DESCRIPTION

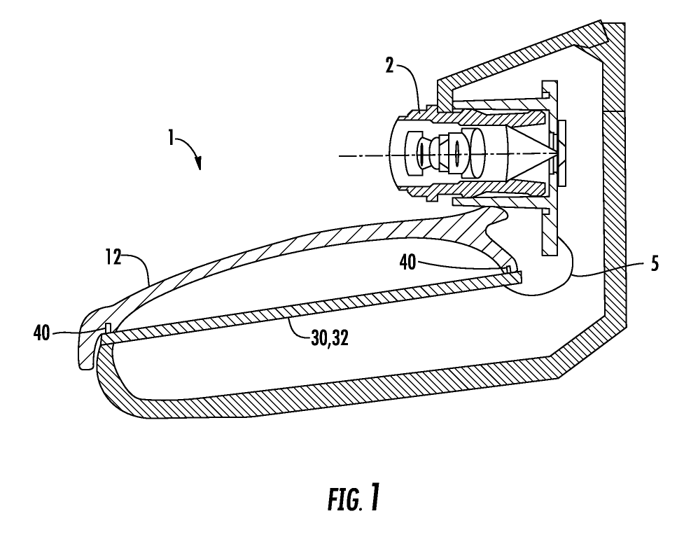

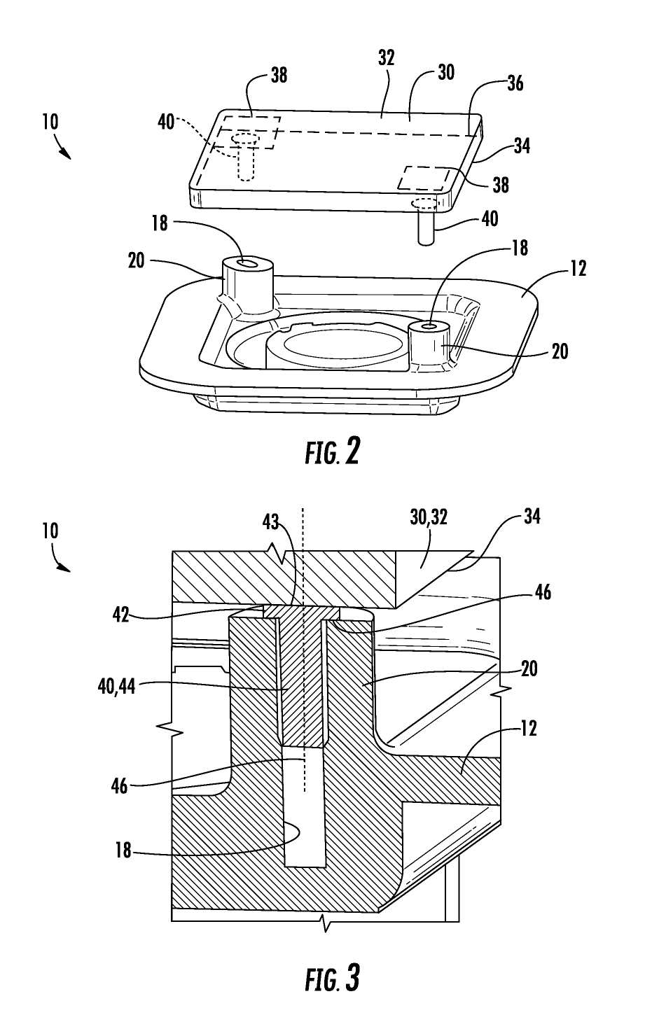

Referring to FIGS. 1 and 2, the PCB assembly 10 includes a housing 12 and a PCB device 30 disposed in the housing 12. The housing 12 is, for example used to support a sensor device such as a camera within a vehicle. In the illustrated embodiment, the camera is configured to be mounted on the interior side of a windshield of the vehicle, and includes an imager module 2. The Imager module 2 is electrically connected to the PCB 30 via a conventional connection, e.g., wire bonds 5 or a flexible line.

The PCB device 30 includes a PCB 32 and a fastener 40 that is secured to a surface of the PCB 32. The PCB 32 mechanically supports and electrically connects electronic components using conductive tracks, pads and other features etched from electrically conductive layers laminated onto a non-conductive substrate. In some embodiments, the electrically conductive layers are formed of copper and the substrate is formed of an electrical insulator such as FR-4 glass epoxy. The electronic components such as a control unit and a data interface, tracks, pads and other features are not shown here for clarity. The PCB 32 has the form of a thin plate, and includes a first surface 34, and an opposed second surface 36. The PCB 32 is illustrated here as having a rectangular peripheral shape, but is not limited to this. For example, the PCB 32 may have any peripheral shape including an irregular peripheral shape to accommodate the interior shape of the housing 12.

The fastener 40 is an elongated rod that includes a base 42 and a shank 44 that protrudes from one side of the base 42 along a longitudinal axis 46 of the fastener 40. The base 42 has a first cross-sectional diameter and the shank 44 has a second cross sectional diameter that is less than the first cross sectional diameter whereby the base 42 is enlarged relative to the shank 44. A shoulder 46 is formed at the intersection of the base 42 and the shank 44 to accommodate the difference in diameters at this location.

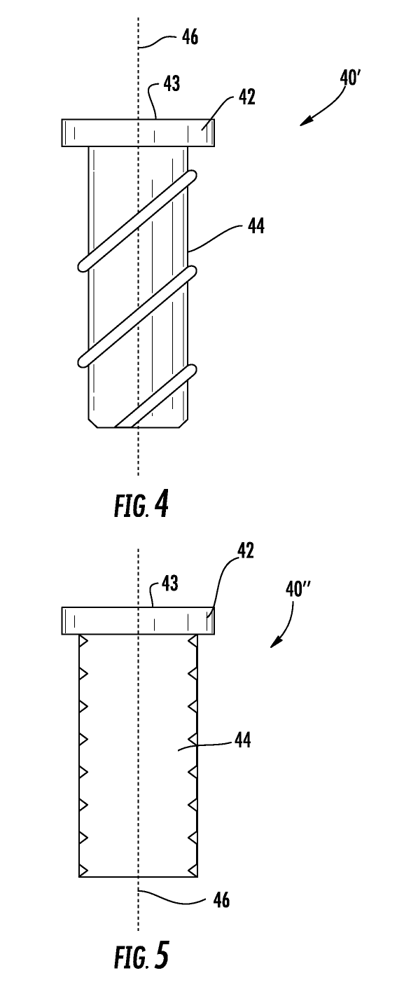

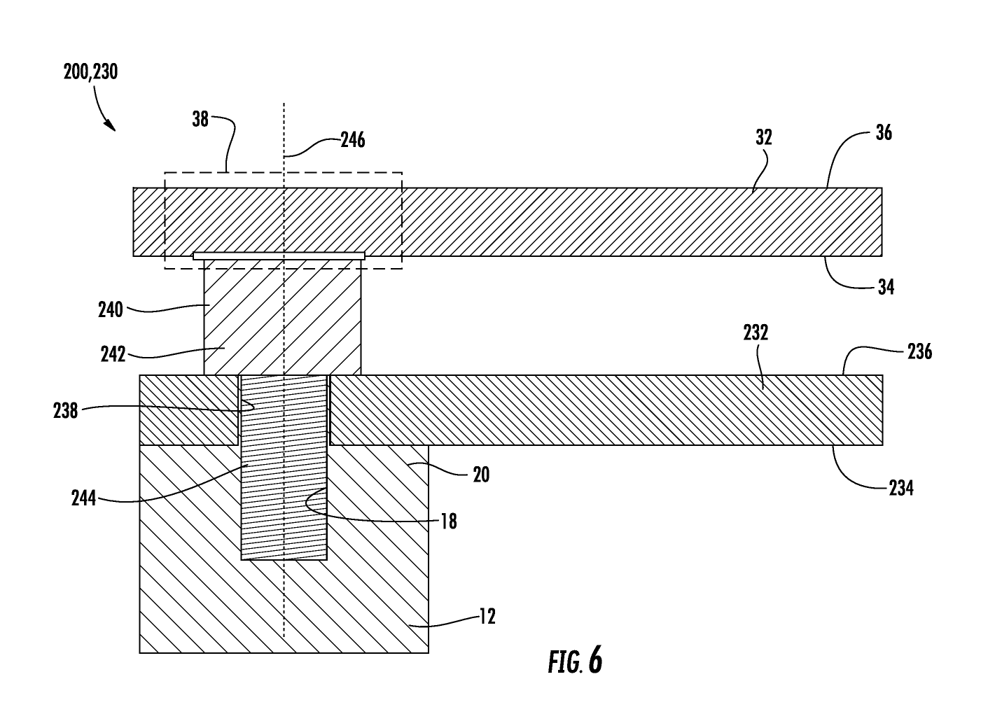

The shank 44 of the fastener 40 is configured to be inserted into an opening 18 of the housing 12 in such a way as to secure the printed circuit board relative to the housing 12. For example, the shank 44 may be shaped and dimensioned to be press fit into the opening 18. In some embodiments, the shank 44 has an outer surface that is free of surface features such as protrusions, recesses and/or textures (FIGS. 2 and 3), and the press-fit is achieved by appropriately shaping and dimensioning the shank 44 relative to the shape and dimensions of the opening 18. In other embodiments, the shank 44 is provided with surface features such as threads (FIG. 4) or knurls (FIG. 5) that further facilitate secure engagement of the fastener 40 with the opening 18 of the housing 12.

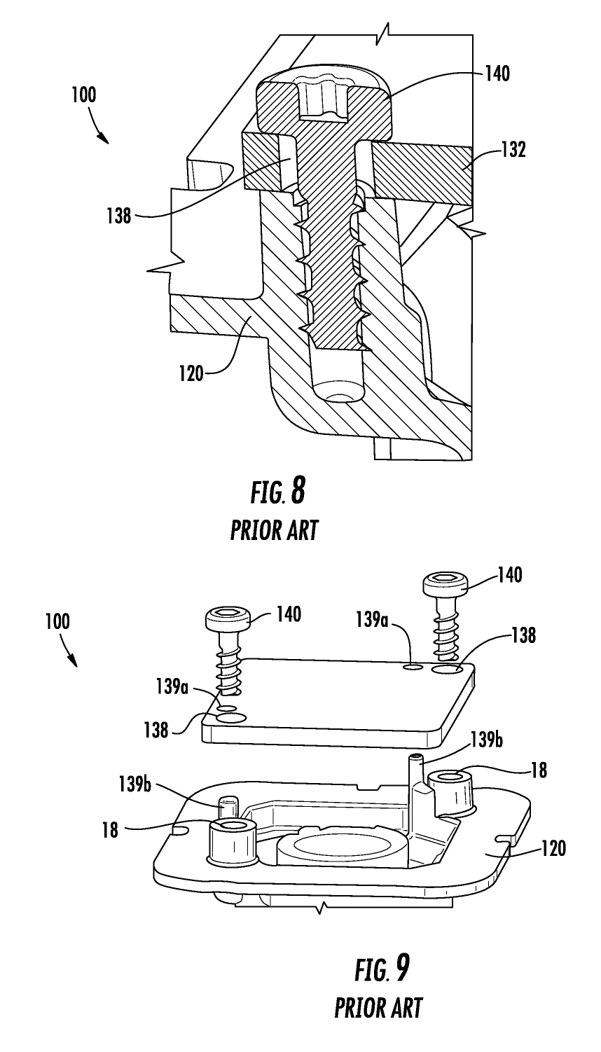

An end face 43 of the fastener base 42 is secured to the first surface 34 of the PCB 32 by soldering or other appropriate joining method. In some embodiments, the fastener base 42 is secured to the first surface 34 in a region of the PCB 32 that is free of openings. This can be compared to some conventional PCB assemblies 100 in which the PCB 132 has an opening 138 (i.e., a through hole) through which a conventional screw 140 is inserted (FIGS. 8 and 9). When the end face 43 is fixed to the first surface 34, the base 42 is disposed between the shank 44 and the first surface 34, and the shank 44 extends away from the PCB 32 in a direction perpendicular to the first surface 34.

In the PCB device 30, the fastener 40 is joined to a surface 34 of the PCB 32. Since the fastener 40 is joined to the surface 34, there is no need to provide a through hole in the PCB 32 to receive the fastener 40. Moreover, both the PCB 32 and the housing 12 may be made free of guide posts and/or location features used for alignment of the through holes of the PCB with the openings of the housing. As a result, the useful area (i.e., the area of the PCB 32 that can include electronic elements) of the PCB 32 is increased relative to some conventional PCB assemblies.

In use, the PCB device 30 is disposed in the housing 12 with the shank 44 disposed within the opening 18 that has been formed in the housing 12 at an appropriate location.

In some embodiments, the housing 12 includes several openings 18 that are strategically located to provide stable support to the PCB 32 within the housing 12. In some embodiments, the openings 18 are formed in bosses 20 that protrude from the housing inner surface. The openings 18 of the housing 12 may have a circular or elongated (e.g., slot) shape when seen in plan view. By providing at least one of the openings 18 with a slot shape, manufacturing tolerance requirements regarding the placement of the openings 18 within the housing 12 and/or fasteners 40 on the PCB 32 may be reduced. In use, the shank 44 of the fastener 40 is inserted into a corresponding opening 18 of the housing to an extent that the shoulder 46 abuts the boss 20 that surrounds the opening 18.

Referring to FIG. 6, an alternative embodiment PCB assembly 200 includes a housing 12 and a PCB device 230 disposed in the housing 12. The PCB device 230 includes elements in common with the PCB device 30 described above with respect to FIGS. 2 and 3, and elements common to both embodiments are referred to by a common reference number. The PCB device 230 includes the PCB 32 (referred to herebelow as the first PCB 32), a second PCB 232, and an alternative embodiment fastener 240 that is secured to the first surface 34 of the first PCB 32. The second PCB 232 includes a first surface 234, and an opposed second surface 236, and a through opening 238 that extends between the first and second surfaces 234, 236 and is configured to receive the shank 244 of the fastener 240 therethrough.

The alternative embodiment fastener 240 is substantially similar to the fastener 40 described above with respect to FIGS. 2 and 3. In particular, the fastener 240 is an elongated rod that includes a base 242 and a shank 244 that protrudes from the base. The base 242 has a first cross-sectional diameter that is greater than the diameter of the through opening 238, and the shank 244 has a second cross sectional diameter that is less than the first cross sectional diameter and less than the diameter of the through opening 238. Like the previous embodiment, the base 242 is enlarged relative to the shank 244, and shoulder 246 is formed at the intersection of the base 242 and the shank 244 to accommodate the difference in diameters at this location. However, the base 242 differs from the previous embodiment in that the base 242 is elongated along the longitudinal axis 246.

In use, the PCB device 230 is secured to the housing 12 via the fastener 240 with the second PCB 232 arranged in a stacked relationship with the first PCB 32. In particular, the first PCB 32 overlies the second PCB 232 with the first surface of the first PCB 32 facing the second PCB 232. The end face of the base 242 of the fastener 240 is fixed to the first PCB first surface 34, and the shank 244 extends through the through opening 238 to an extent that the shoulder 246 abuts the second surface 236 of the second PCB 232. Thus, the base 242 serves as a stand-off that maintains a desired spacing between the first PCB 32 and the second PCB 232. As in the previously described assembly, the shank 244 of the fastener 240 is inserted into an opening 18 of the housing 12 in such a way as to secure the first and second PCBs 32, 232 relative to the housing 12. In particular, the shank 244 of the fastener 240 is inserted into a corresponding opening 18 of the housing 12 to an extent that the first surface 234 of the second PCB 232 abuts the boss 20 that surrounds the opening 18.

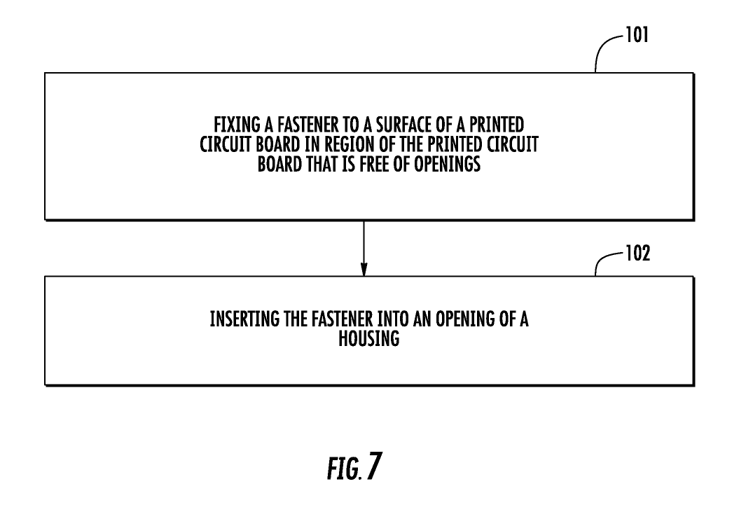

Referring to FIG. 7, a method of assembling a printed circuit board assembly includes the following method steps:

Initially, the fastener 40, 240 is fixed to the first surface 34 of the PCB 32 in a region 38 that is free of openings (101). The fastener 40, 240 is joined to the first surface 34 using known methods such as soldering.

The PCB 32 is joined to the housing 12 by inserting the fastener 40, 242 into an opening 18 of a housing 12 to form a press fit connection between the fastener 40, 242 and the housing 12 (102). The fastener 40 is configured to provide a press-fit connection between the shank 44, 244 and an inner surface of the opening 18. To overcome any resistance to insertion, and to ensure a complete insertion of the shank 44, 244 into the opening 18, a force is applied to the second surface 236 of the PCB 32 at a location that is aligned with the fastener 40, 240. The force, indicated by arrows in FIG. 2, urges the fastener 40, 240 into the press fit connection with the opening 18 of the housing 12.

When assembling the alternative embodiment printed circuit board assembly 230 illustrated in FIG. 6, the method includes an additional step. In particular, prior to inserting the fastener 240 into the opening 18 of the housing 12, the method includes inserting the fastener shank 244 into the through hole 238 of the second PCB 232 such that the fastener shank 244 extends through the through hole 238. This step provides the stacked arrangement of the first PCB 32 and the second PCB 232, with the fastener base 242 disposed between and separating the first PCB 32 and the second PCB 232.

In the embodiments illustrated in FIGS. 2, 3 and 6, the fastener 40, 240 includes a base 42, 242 that is enlarged in diameter relative to the shank 44, 244. By providing the enlarged base 42, 242 the area of the fastener 40, 240 used to form the attachment with the first surface 34 of the PCB 32 is sufficient to form a secure mechanical connection and stability of the fastener 40 with respect to lateral forces is increased. However, in some embodiments, the fastener 40 of FIGS. 2 and 3 may be formed having the base 42 and shank 44 of the same outer diameter, whereby the fastener 40 may have a uniform outer diameter along its length.

Selective illustrative embodiments of the cell including an elastically compliant cell terminal are described above in some detail. It should be understood that only structures considered necessary for clarifying the cell have been described herein. Other conventional structures, and those of ancillary and auxiliary components of the battery system, are assumed to be known and understood by those skilled in the art. Moreover, while working examples of the cell been described above, the cell is not limited to the working examples described above, but various design alterations may be carried out without departing from the device as set forth in the claims.

What is claimed, is:

1. A printed circuit board device comprising
a printed circuit board that includes electrically conductive layers laminated onto a non-conductive substrate, the printed circuit board having
a first surface,
an opposed second surface, and
an opening-free region; and
a fastener disposed within the opening free region and protruding from one of the first surface and the second surface, the fastener configured to be press fit into an opening of a housing in such a way as to secure the printed circuit board relative to the housing.

2. The printed circuit board device of claim 1, wherein the fastener is fixed to the one of the first surface and the second surface.

3. The printed circuit board device of claim 2, wherein the fastener is soldered to the one of the first surface and the second surface.

4. The printed circuit board device of claim 1, wherein the fastener is an elongated rod.

5. The printed circuit board device of claim 1, wherein the fastener includes surface features that enhance engagement with a surface of the opening.

6. The printed circuit board device of claim 5, wherein the surface features comprise a helical thread.

7. The printed circuit board device of claim 5, wherein the surface features comprise a knurl.

8. The printed circuit board device of claim 1, wherein the fastener includes a base having a first cross-sectional diameter and a shank that protrudes from the base and has a second cross sectional diameter, where the second cross sectional diameter is less than the first cross sectional diameter.

9. The printed circuit board device of claim 1, wherein the printed circuit board is free of guide posts and free of location features for locating guide posts of a housing.

10. A printed circuit board assembly including a housing and a printed circuit board device disposed in the housing, wherein
the housing defines an opening, and
the printed circuit board device includes
a printed circuit board that includes electrically conductive layers laminated onto
a non-conductive substrate, the printed circuit board having
a first surface,
an opposed second surface,
an opening-free region; and
a fastener disposed within the opening free region and protruding from one of the first surface and the second surface, the fastener including a size and shape such that the fastener is press fit into the opening in such a way as to secure the printed circuit board relative to the housing.

11. The printed circuit board assembly of claim 10, wherein the fastener is an elongated rod.

12. The printed circuit board assembly of claim 10, wherein the fastener includes surface features that enhance engagement with a surface of the opening.

13. The printed circuit board assembly of claim 10, wherein the fastener includes a base having a first cross-sectional diameter and a shank that protrudes from the base and has a second cross sectional diameter, wherein the second cross sectional diameter is less than the first cross sectional diameter, and a shoulder is disposed at the intersection of the base and the shank.

14. The printed circuit board assembly of claim 13, further comprising a second printed circuit board having a through hole, the second printed circuit board disposed between the first printed circuit board and the housing, wherein the fastener passes through the through hole and the shoulder abuts a surface of the second printed circuit board.

15. The printed circuit board assembly of claim 10, wherein
the fastener includes a base and a shank that protrudes from the base,
one end of the base adjoins the one of the first surface and the second surface and an opposed end of the base adjoins the shank,
the base is disposed between the shank and the one of the first surface and the second surface, and
the shank extends away from the printed circuit board in a direction perpendicular to the one of the first surface and the second surface.

16. The printed circuit board assembly of claim 10, wherein
the printed circuit board is free of guide posts and free of location features for locating guide posts of a housing, and
the housing is free of guide posts and free of location features for locating guide posts of a printed circuit board.

17. A method of assembling a printed circuit board assembly, the method comprising
fixing a fastener to a first surface of a printed circuit board in region of the printed circuit board that is free of openings;
inserting the fastener into an opening of a housing to form a press fit connection between the fastener and the housing.

18. The method of claim 17, wherein the step of fixing a fastener to a surface of a printed circuit board comprises soldering the fastener to the surface of the printed circuit board.

19. The method of claim 17, further comprising applying a force to a second surface of the printed circuit board at a location that is aligned with the fastener, wherein the second surface is opposed to the first surface and the force urges the fastener into the press fit connection with the opening of the housing.

20. The method of claim 17, wherein the inserting step includes, prior to inserting the fastener into the opening of the housing, inserting the fastener into a through hole of a second printed circuit board such that the fastener extends through the through hole.
